(19) United States
(12) Patent Application Publication
(10) Pub. No.: US 2026/0144110 A1
(43) Pub. Date: May 21, 2026

(54) WIRING SUBSTRATE, STACKED WIRING SUBSTRATE, AND SEMICONDUCTOR DEVICE

(71) Applicant: Shinko Electric Industries Co., LTD., Nagano-shi (JP)

(72) Inventor: Kyota Yamamura, Nagano-shi (JP)

(73) Assignee: Shinko Electric Industries Co., LTD., Nagano-shi (JP)

(21) Appl. No.: 19/392,503

(22) Filed: Nov. 18, 2025

(30) Foreign Application Priority Data
Nov. 20, 2024 (JP) 2024-202394

(51) Int. Cl. H01L 23/498

(52) U.S. Cl. CPC H10W 70/65; H10W 70/685; H10W 90/401

(57) ABSTRACT

A wiring substrate includes a first wiring structure and a second wiring structure formed on the first wiring structure and having a higher wiring density than the first wiring structure. The first wiring structure includes a first wiring layer, a first insulation layer covering the first wiring layer, and a second wiring layer extending through the first insulation layer and electrically connected to the first wiring layer. The second wiring structure includes a second insulation layer formed on an upper surface of the first insulation layer, multiple via wirings extending through the second insulation layer, and a third wiring layer formed on the upper surface of the second insulation layer and electrically connected to the second wiring layer by the via wirings. The second insulation layer has a lower filler content ratio than the first insulation layer.

### CROSS-REFERENCE TO RELATED APPLICATIONS

This application is based upon and claims the benefit of priority from Japanese Patent Application No. 2024-202394, filed on Nov. 20, 2024, the entire contents of which are incorporated herein by reference.

### BACKGROUND

### 1. Field

This disclosure relates to a wiring substrate, a stacked wiring substrate, a semiconductor device, and a method for manufacturing a wiring substrate.

### 2. Description of Related Art

A typical wiring substrate on which electronic components such as semiconductor chips are mounted may include multiple wiring layers and multiple insulation layers that are alternately stacked through a build-up process. For example, JP2015-191968A proposes that this type of wiring substrate have a low-density wiring structure including an insulation layer formed from a non-photosensitive thermosetting resin and a high-density wiring structure including an insulation layer formed from a photosensitive resin and formed on the low-density wiring structure.

In the wiring substrate described above, the upper surface of the uppermost insulation layer and the upper end surface of the uppermost wiring layer in the low-density wiring structure are polished to be flush with each other, and then a wiring layer in the high-density wiring structure is formed on the upper surface of the uppermost insulation layer.

### SUMMARY

In the wiring substrate described above, it is desirable that the reliability of electrical connection between the wiring layer in the low-density wiring structure and the wiring layer in the high-density wiring structure be improved.

In an aspect, a wiring substrate includes a first wiring structure and a second wiring structure formed on an upper surface of the first wiring structure and having a higher wiring density than the first wiring structure. The first wiring structure includes a first wiring layer, a first insulation layer covering the first wiring layer, and a second wiring layer extending through the first insulation layer in a thickness-wise direction and electrically connected to the first wiring layer, the second wiring layer including an upper end surface exposed from an upper surface of the first insulation layer. The second wiring structure includes a second insulation layer formed on the upper surface of the first insulation layer, multiple through holes extending through the second insulation layer in the thickness-wise direction and exposing part of the upper end surface of the second wiring layer, multiple via wirings respectively filling the through holes, and a third wiring layer formed on an upper surface of the second insulation layer and electrically connected to the second wiring layer by the via wirings. A content ratio of filler in the second insulation layer is lower than a content ratio of filler in the first insulation layer.

Other features and aspects will be apparent from the following detailed description, the drawings, and the claims.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

FIG. 1 is a schematic cross-sectional view illustrating an embodiment of a wiring substrate.

FIG. 2 is a schematic cross-sectional view illustrating, in an enlarged manner, part of the wiring substrate of the embodiment.

FIG. 3 is a schematic plan view illustrating part of the wiring substrate of the embodiment.

FIG. 4 is a schematic cross-sectional view illustrating an embodiment of a semiconductor device.

FIGS. 5, 6, 7, 8, 9, 10, 11, 12, 13, 14, 15, 16, 17, 18, 19, 20 and 21 are schematic cross-sectional views illustrating a method for manufacturing the wiring substrate of the embodiment.

FIG. 22 is a schematic cross-sectional view illustrating a method for manufacturing an embodiment of a stacked wiring substrate.

FIG. 23 is a schematic plan view illustrating part of a wiring substrate in a modified example.

FIG. 24 is a schematic plan view illustrating part of a wiring substrate in a modified example.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

An embodiment of the present disclosure will now be described with reference to the accompanying drawings.

In the cross-sectional views, to facilitate understanding of the cross-sectional structure of each member, hatching lines may be replaced by shadings or may not be illustrated. In the plan views, hatching lines may be added to some of the members to facilitate understanding of the planar shape of each member. In the description of the present disclosure, a numerical range of “X1 to X2” defined by the lower limit value X1 and the upper limit value X2 refers to a range that is greater than or equal to X1 and less than or equal to X2, unless otherwise specified.

### Structure of Wiring Substrate 10

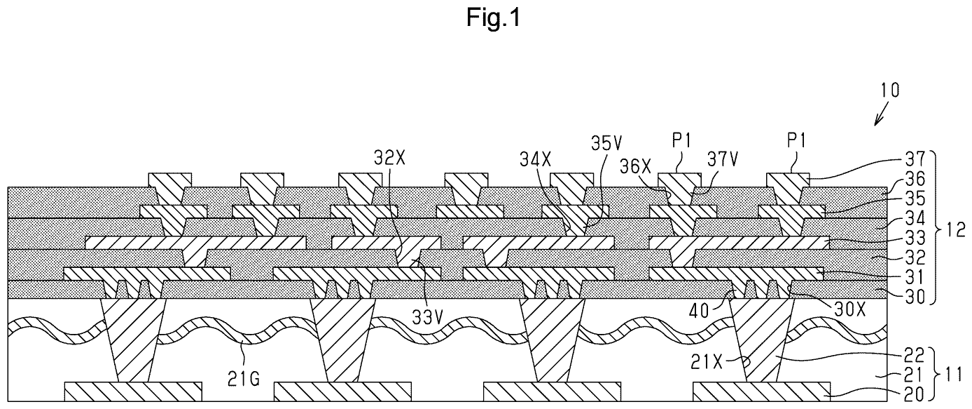

FIG. 1 illustrates a wiring substrate 10 that includes a first wiring structure 11 and a second wiring structure 12. The first wiring structure 11 includes a wiring layer 20, an insulation layer 21, and a wiring layer 22. The second wiring structure 12 is arranged on one side of the first wiring structure 11. The second wiring structure 12 is a high-density wiring structure (fine wiring structure) that includes a wiring layer having a higher wiring density than that of the first wiring structure 11. The second wiring structure 12 includes an insulation layer 30, a wiring layer 31, an insulation layer 32, a wiring layer 33, an insulation layer 34, a wiring layer 35, an insulation layer 36, and a wiring layer 37.

In the present embodiment, with reference to FIG. 1, the side of the wiring substrate 10 at which the wiring layer 37 is located is referred to as the upper side or one side. The side of the wiring substrate 10 at which the wiring layer 20 is located is referred to as the lower side or the other side. In the present embodiment, for the sake of convenience, the surface of each element located at the wiring layer 37 is referred to as the upper surface or one surface of the element. The surface of each element located at the wiring layer 20 is referred to as the lower surface or the other surface of the element. The wiring substrate 10 may be used in a state reversed, upside down, or be arranged at any angle. In this specification, the term “plan view” refers to a view of an object in the normal direction of one surface of the wiring layer 37. The term “planar shape” refers to a shape of an object as viewed in the normal direction of one surface of the wiring layer 37.

The wiring substrate 10 may have any planar shape and any planar size. The planar shape of the wiring substrate 10 is, for example, rectangular. The planar size of the wiring substrate 10 may be, for example, approximately 30 mm×30 mm to 50 mm×50 mm.

### Structure of First Wiring Structure 11

The wiring layer 20 is the lowermost wiring layer in the first wiring structure 11 and also is the lowermost wiring layer in the wiring substrate 10. The lower surface of the wiring layer 20 is exposed from the lower surface of the insulation layer 21. The lower surface of the wiring layer 20 is, for example, flush with the lower surface of the insulation layer 21. The wiring layer 20 serves as, for example, an external connection terminal used for electrical connection with another wiring substrate. The material of the wiring layer 20 may be, for example, copper (Cu) or a copper alloy. The thickness of the wiring layer 20 may be, for example, approximately 10 μm to 30 μm. The line/space (L/S) of the wiring layer 20 may be, for example, approximately 10 μm/10 μm to 50 μm/50 μm. In the term “line/space”, line represents the width of a wiring, and space represents the distance between adjacent wirings (inter-wiring distance). For example, when the line/space is 10 μm/10 μm to 50 μm/50 μm, the width of a wiring is greater than or equal to 10 μm and less than or equal to 50 μm. The distance between adjacent wirings is greater than or equal to 10 μm and less than or equal to 50 μm. The width of a wiring does not necessarily have to be equal to the inter-wiring distance.

The wiring layer 20 may have any planar shape and any planar size. The planar shape of the wiring layer 20 is, for example, circular. The diameter of the wiring layer 20 may be, for example, approximately 90 μm to 110 μm.

The insulation layer 21 covers the upper and side surfaces of the wiring layer 20 and exposes the lower surface of the wiring layer 20. The insulation layer 21 is the lowermost insulation layer in the first wiring structure 11 and also is the uppermost insulation layer in the first wiring structure 11. The insulation layer 21 includes a non-photosensitive resin as a main component. The main component of the insulation layer 21 may be, for example, a thermosetting non-photosensitive resin, such as an epoxy resin, an imide resin, a phenol resin, a cyanate resin, or the like. The insulation layer 21, for example, includes a thermosetting non-photosensitive resin as the main component and includes a reinforcement member 21G. The insulation layer 21 has a higher rigidity than the insulation layers 30, 32, 34, and 36 included in the second wiring structure 12. The insulation layer 21 may be formed by impregnating the reinforcement member 21G with a thermosetting non-photosensitive resin. The reinforcement member 21G may be, for example, a non-woven fabric or a woven fabric formed of a glass fiber, a carbon fiber, an aramid fiber, or the like. The thickness of the insulation layer 21 may be, for example, approximately 30 μm to 80 μm.

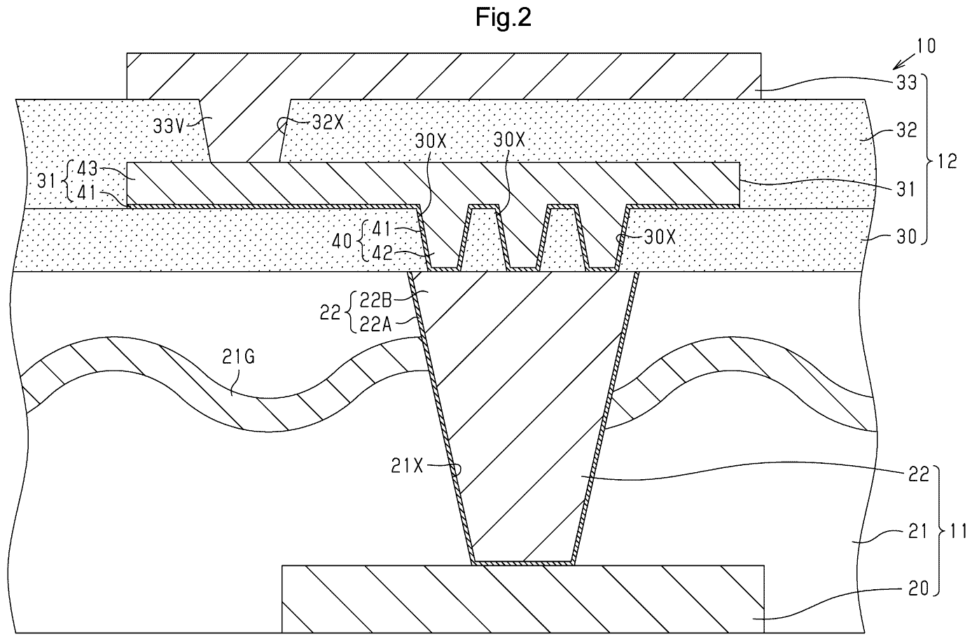

As illustrated in FIGS. 1 and 2, the wiring layer 22 includes via wirings (connection vias) embedded in the insulation layer 21. For example, through hole 21X extend through the insulation layer 21 in the thickness-wise direction and expose part of the upper surface of the wiring layer 20, and the through holes 21X are filled with the via wirings defining the wiring layer 22. The wiring layer 22 is electrically connected to the wiring layer 20. The wiring layer 22 is the uppermost wiring layer in the first wiring structure 11. For the sake of simplicity, FIG. 2 does not illustrate the insulation layers 34 and 36 and the wiring layers 35 and 37.

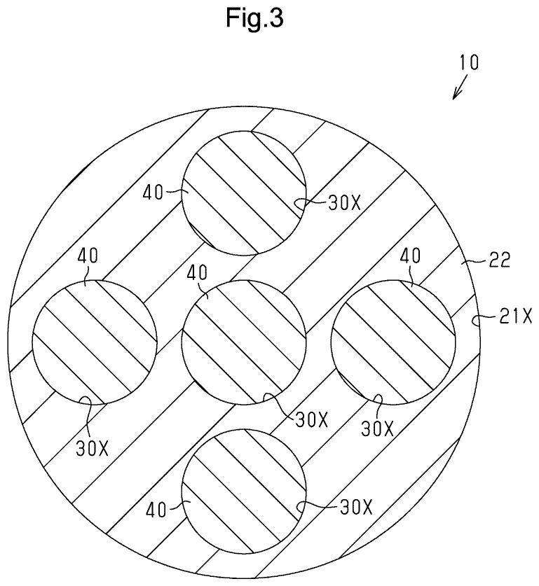

As illustrated in FIG. 3, the planar shape of the wiring layer 22 is, for example, circular. The planar shape of the wiring layer 20 is not limited to the circular shape and may be any shape.

As illustrated in FIG. 2, the wiring layer 22 is tapered to have a diameter that decreases from the upper side (close to the second wiring structure 12) toward the lower side (close to the wiring layer 20) in FIG. 2. The wiring layer 22 has the form of, for example, a reversed truncated cone so that its upper end surface has a larger diameter than its lower end surface. The upper end surface of the wiring layer 22 is exposed from the insulation layer 21. The upper end surface of the wiring layer 22 is, for example, flush with the upper surface of the insulation layer 21. The upper end surface of the wiring layer 22 and the upper surface of the insulation layer 21 include, for example, a polished surface. The diameter of the upper end surface of the wiring layer 22 may be, for example, approximately 60 μm to 80 μm. The material of the wiring layer 22 may be, for example, copper or a copper alloy.

The wiring layer 22 includes a seed layer 22A formed on the wall surface of the through hole 21X and a metal layer 22B formed in the through hole 21X on an inner side of the seed layer 22A.

The seed layer 22A is formed to cover the entire wall surface of the through hole 21X, namely, the entire wall surface of the through hole 21X and the entire upper surface of the wiring layer 20 exposed at the bottom of the through hole 21X. In an example, the seed layer 22A is not formed on the upper surface of the insulation layer 21. The seed layer 22A may be, for example, an electroless plating film formed by electroless plating or a film formed by sputtering.

The metal layer 22B is formed so as to fill the through hole 21X on the inner side of the seed layer 22A. The metal layer 22B is formed to cover the entire surface of the seed layer 22A. The metal layer 22B may be, for example, an electrolytic plating layer formed by electrolytic plating. The material of the metal layer 22B may be, for example, copper or a copper alloy.

### Structure of Second Wiring Structure 12

As illustrated in FIG. 1, the second wiring structure 12 is stacked on the upper surface of the first wiring structure 11. The second wiring structure 12 is stacked on the upper surface of the insulation layer 21 and the upper surface of the wiring layer 22.

In the second wiring structure 12, the insulation layers 30, 32, 34, and 36 each include, for example, a photosensitive resin as a main component. The material of the insulation layers 30, 32, 34, and 36 may be, for example, a photosensitive insulating resin including a phenol resin, a polyimide resin, or the like, as a main component. The insulation layers 30, 32, 34, and 36 may include, for example, a filler such as silica or alumina. The content ratio of the filler in each of the insulation layers 30, 32, 34, and 36 is lower than the content ratio of the filler in the insulation layer 21. In the present embodiment, the insulation layers 30, 32, 34, and 36 do not include a filler. The thickness of each of the insulation layers 30, 32, 34, and 36 is smaller than the thickness of the insulation layer 21. The thickness of each of the insulation layers 30, 32, 34, and 36 may be, for example, approximately 5 μm to 10 μm.

In the second wiring structure 12, the material of the wiring layers 31, 33, 35, and 37 may be copper or a copper alloy. The thickness of each of the wiring layers 31, 33, 35, and 37 is smaller than the thickness of the wiring layer 20. The thickness of each of the wiring layers 31, 33, and 35 may be, for example, approximately 1 μm to 3 μm. The thickness of the wiring layer 37 may be, for example, approximately 5 μm to 15 μm. Each of the wiring layers 31, 33, 35, 37 has a higher wiring density than the wiring layer 20, that is, has a smaller line/space (L/S) than the wiring layer 20. The line/space of the wiring layers 31, 33, 35, and 37 may be approximately 1 μm/1 μm to 3 μm/3 μm.

### Structure of Insulation Layer 30

The insulation layer 30 is stacked on the upper surface of the insulation layer 21 to cover the upper end surface of the wiring layer 22. The insulation layer 30 covers, for example, the entire upper surface of the insulation layer 21. The insulation layer 30 is the lowermost insulation layer in the second wiring structure 12.

As illustrated in FIG. 2, a through hole 30X extends through the insulation layer 30 in the thickness-wise direction and exposes part of the upper end surface of the wiring layer 22 in a given location. Multiple through holes 30X are formed for each connection via of the wiring layer 22. As illustrated in FIG. 3, in the present embodiment, five through holes 30X are formed for each connection via of the wiring layer 22. In an example, the five through holes 30X are arranged on the wiring layer 22 separately from each other. The five through holes 30X are arranged, for example, in a cross in plan view. For example, of the five through holes 30X, three through holes 30X are arranged side by side in the horizontal direction in the drawing, and three through holes 30X are arranged side by side in the vertical direction in the drawing. Each through hole 30X may have any planar shape and any planar size. The planar shape of each through hole 30X is, for example, circular.

As illustrated in FIG. 2, the diameter of each through hole 30X is smaller than the diameter of the through hole 21X. The through hole 30X is tapered to have a diameter that decreases from the upper side (close to the wiring layer 31) toward the lower side (close to the wiring layer 22) in FIG. 2. For example, the through hole 30X has the form of a reversed truncated cone so that the lower open end has a smaller diameter than the upper open end.

The diameter of the upper open end of the through hole 30X may be, for example, approximately 10 μm to 15 μm.

Structure of Wiring Layer 31

The wiring layer 31 is stacked on the upper surface of the insulation layer 30. The wiring layer 31 is the lowermost wiring layer in the second wiring structure 12. The wiring layer 31 is electrically connected to the wiring layer 22 through a via wiring 40 formed in the through hole 30X. The wiring layer 31 is formed integrally with multiple via wirings 40 filling multiple through holes 30X. Each wiring pattern of the wiring layer 31 is electrically connected to the corresponding connection via of the wiring layer 22 by the multiple via wirings 40. Thus, multiple (five in the present embodiment) via wirings 40 are connected to a single connection via of the wiring layer 22. In some examples, the number of the via wirings 40 arranged on the upper surface of the connection via (i.e., wiring layer 22) is five or more. Additionally, two or more of the via wirings 40 are arranged side by side in at least one direction on the upper surface of the connection via (wiring layer 22). In the example illustrated in FIGS. 2 and 3, three of the via wirings 40 are arranged side by side in the at least one direction on the upper surface of the connection via (wiring layer 22).

Each via wiring 40 fills the through hole 30X and thus has the same structure as the through hole 30X. Each via wiring 40 has the form of an inverted truncated cone having a diameter that is greater at the upper surface than at the lower surface. As illustrated in FIG. 3, the planar size of each via wiring 40 is set to be smaller than the planar size of the wiring layer 22. The diameter of the upper surface of each via wiring 40 is smaller than the diameter of the upper end surface of the wiring layer 22. The diameter of the upper surface of each via wiring 40 is set to, for example, approximately 0.1 to 0.3 times the diameter of the upper end surface of the wiring layer 22. The diameter of the upper surface of each via wiring 40 may be, for example, approximately 10 μm to 15 μm. The distance between adjacent ones of the via wirings 40 may be, for example, approximately 10 μm to 15 μm. To illustrate the relationship between the through hole 21X and the wiring layer 22 with the through holes 30X and the via wirings 40, FIG. 3 does not illustrate the remaining members.

As illustrated in FIG. 2, the via wirings 40 include a seed layer 41 that covers the wall surfaces of the through holes 30X and a metal layer 42 that is formed in the through holes 30X on an inner side of the seed layer 41.

The seed layer 41 is formed to continuously cover the wall surfaces of the through holes 30X and the upper surface of the insulation layer 30. The seed layer 41 continuously covers the entire upper end surface of the wiring layer 22 exposed at the bottom of each through hole 30X, the entire wall surface of the through hole 30X, and the upper surface of the insulation layer 30. The seed layer 41 may be, for example, a sputtered film. The seed layer 41 formed by sputtering may be, for example, a metal film having a double-layered structure in which a Ti layer formed of titanium (Ti) and a Cu layer formed of copper (Cu) are sequentially stacked on the wall surface of the through hole 30X. In this case, the thickness of the Ti layer may be, for example, approximately 20 nm to 50 nm, and the thickness of the Cu layer may be, for example, approximately 100 nm to 300 nm. The Ti layer is used as a metal barrier film that inhibits dispersion of copper from the Cu layer or the metal layer 42 (e.g., Cu layer) to the insulation layer 30. The material of the metal film serving as the metal barrier film is not limited to Ti and may be titanium nitride (TiN), tantalum nitride (TaN), tantalum (Ta), chromium (Cr), or the like.

The metal layer 42 fills the through hole 30X on the inner side of the seed layer 41. The metal layer 42 covers the entire surface of the seed layer 41. The metal layer 42 may be, for example, an electrolytic plating layer. The material of the metal layer 42 may be, for example, copper or a copper alloy.

The wiring layer 31 includes a seed layer 41 formed on the upper surface of the insulation layer 30 and a metal layer 43 formed on the upper surface of the seed layer 41.

The seed layer 41 covers the upper surface of the insulation layer 30 located around the through hole 30X. The metal layer 43 is formed on the seed layer 41, formed on the upper surface of the insulation layer 30, and on the metal layer 42. The metal layer 43 is formed continuously and integrally with the metal layer 42. The material of the metal layer 43 may be, for example, copper or a copper alloy. The metal layer 43 may be, for example, an electrolytic plating layer.

### Structure of Insulation Layer 32

The insulation layer 32 is stacked on the upper surface of the insulation layer 30 to cover the wiring layer 31. Through holes 32X extend through the insulation layer 32 in the thickness-wise direction to expose part of the upper surface of the wiring layer 31 in given locations. For example, the through holes 32X do not overlap the through holes 21X in plan view. For example, the through holes 32X do not overlap the through holes 30X in plan view.

### Structure of Wiring Layer 33

The wiring layer 33 is stacked on the upper surface of the insulation layer 32. The wiring layer 33 is electrically connected to the wiring layer 31 through a via wiring 33V formed in the through hole 32X. The wiring layer 33 is formed continuously and integrally with the via wiring 33V. The via wiring 33V, for example, fills the through hole 32X.

As illustrated in FIG. 1, the insulation layer 34 is stacked on the upper surface of the insulation layer 32 to cover the wiring layer 33. Through holes 34X extend through the insulation layer 34 in the thickness-wise direction to expose part of the upper surface of the wiring layer 33 in given locations.

The wiring layer 35 is stacked on the upper surface of the insulation layer 34. The wiring layer 35 is electrically connected to the wiring layer 33 through via wirings 35V formed in the through holes 34X. The wiring layer 35 is formed continuously and integrally with the via wirings 35V. The via wirings 35V, for example, fill the through holes 34X.

The insulation layer 36 is stacked on the upper surface of the insulation layer 34 to cover the wiring layer 35. Through holes 36X extend through the insulation layer 36 in the thickness-wise direction to expose parts of the upper surface of the wiring layer 35 in given locations.

The wiring layer 37 is stacked on the upper surface of the insulation layer 36. The wiring layer 37 is formed in the uppermost layer of the wiring substrate 10. The wiring layer 37 is electrically connected to the wiring layer 35 through via wirings 37V formed in the through holes 36X. The wiring layer 37 is formed continuously and integrally with the via wirings 37V. The via wirings 37V, for example, fill the through holes 36X. The wiring layer 37 includes pads P1. The pads P1 serve as electronic component mounting pads for electrical connection to an electronic component such as a semiconductor chip. The planar shape of each pad P1 may be, for example, circular and have a diameter of approximately 20 μm to 30 μm. The pitch between pads P1 may be, for example, approximately 40 μm to 60 μm. The thickness of each pad P1 may be, for example, approximately 10 μm to 15 μm.

A surface-processed layer may be formed on the surface (side surface and upper surface or only upper surface) of the pads P1. In an example, the surface-processed layer includes a gold (Au) layer, a nickel (Ni) layer/Au layer (metal layer formed by stacking the Ni layer and the Au layer in this order), and a Ni layer/palladium (Pd) layer/Au layer (metal layer formed by stacking the Ni layer, the Pd layer, and the Au layer in this order). In an example, the surface-processed layer includes a Ni layer/Pd layer (metal layer in which Ni layer and Pd layer are formed in this order), a Pd layer/Au layer (metal layer in which Pd layer and Au layer are formed in this order), or the like. The Au layer is a metal layer of Au or a Au alloy. The Ni layer is a metal layer of Ni or a Ni alloy. The Pd layer is a metal layer of Pd or a Pd alloy. For example, the Au layer, the Ni layer, and the Pd layer may each be a metal layer formed by electroless plating or a metal layer formed by electrolytic plating. The surface-processed layer may be an organic solderability preservative (OSP) film formed on the surface of each pad P1 through an anti-oxidation process such as an OSP process. The OSP film may be an organic coating of an azole compound or an imidazole compound.

When a surface-processed layer is formed on the surfaces of the pads P1, the surface-processed layer serves as pads for mounting electronic components.

### Structure of Semiconductor Device 1

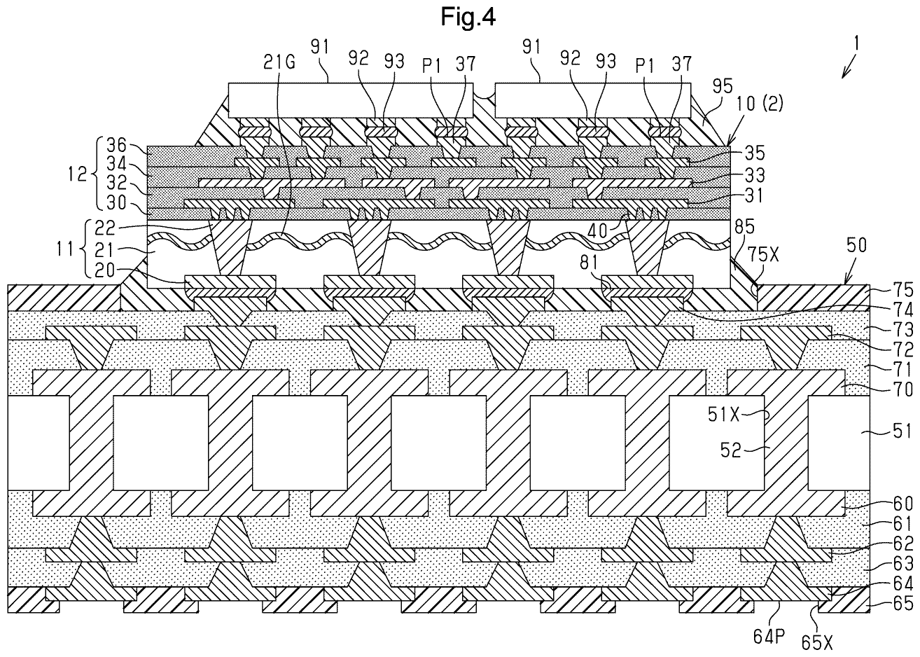

The structure of a semiconductor device 1 will now be described with reference to FIG. 4.

As illustrated in FIG. 4, the semiconductor device 1 includes a stacked wiring substrate 2, one or more (two in the present embodiment) semiconductor chips 91 mounted on the stacked wiring substrate 2, and an underfill resin 95.

### Structure of Stacked Wiring Substrate 2

The stacked wiring substrate 2 includes a wiring substrate 50 and a wiring substrate 10 mounted on the wiring substrate 50. The stacked wiring substrate 2 includes, for example, an underfill resin 85 formed in a gap between the wiring substrate 50 and the wiring substrate 10.

### Structure of Wiring Substrate 50

The wiring substrate 50 includes a core layer 51. The core layer 51 is located, for example, in a central portion of the wiring substrate 50 in the thickness-wise direction. The material of the core layer 51 may be, for example, a glass epoxy substrate obtained by impregnating a glass cloth, which is a reinforcement member, with a non-photosensitive thermosetting resin, which includes an epoxy resin as a main component, and curing the resin. The reinforcement material is not limited to the glass cloth and may be, for example, a glass non-woven cloth, an aramid woven cloth, or an aramid non-woven cloth. The thermosetting insulating resin is not limited to an epoxy resin and may be, for example, a resin material such as an imide resin, a phenol resin, a cyanate resin, or the like. The thickness of the core layer 51 may be, for example, approximately 60 μm to 400 μm.

The core layer 51 includes through holes 51X at given locations (six locations in FIG. 1). The through holes 51X extend through the core layer 51 in the thickness-wise direction. A through-electrode 52 extending through the core layer 51 in the thickness-wise direction is formed in each through hole 51X. The through-electrode 52, for example, fills the through hole 51X. The material of the through-electrode 52 may be, for example, copper or a copper alloy.

The wiring substrate 50 has a wiring structure in which a wiring layer 60, an insulation layer 61, a wiring layer 62, an insulation layer 63, a wiring layer 64, and a solder resist layer 65 are sequentially stacked on the lower surface of the core layer 51. The wiring substrate 50 also has a wiring structure (third wiring structure) in which a wiring layer 70, an insulation layer 71, a wiring layer 72, an insulation layer 73, a wiring layer 74, and a solder resist layer 75 are sequentially stacked on the upper surface of the core layer 51. Here, the wiring layers 60, 62, 64, 70, 72, and 74 included in the wiring substrate 50 have a lower wiring density, that is, a larger line and space (L/S), than the wiring layers 31, 33, 35, and 37 included in the second wiring structure 12 of the wiring substrate 10. The line and space (L/S) of the wiring layers 60, 62, 64, 70, 72, and 74 may be, for example, approximately 20 μm/20 μm to 30 μm/30 μm.

The material of the wiring layers 60, 62, 64, 70, 72, and 74 may be, for example, copper or a copper alloy. The insulation layers 61, 63, 71, and 73 each include, for example, a non-photosensitive resin as a main component. The main component of the insulation layers 61, 63, 71, and 73 may be, for example, a thermosetting non-photosensitive resin such as an epoxy resin, an imide resin, a phenol resin, or a cyanate resin. The insulation layers 61, 63, 71, and 73 may include, for example, a filler such as silica or alumina. The solder resist layers 65 and 75 are each, for example, an insulation layer including a photosensitive resin as a main component. The material of the solder resist layers 65 and 75 may be, for example, a photosensitive insulating resin including a phenol resin, a polyimide resin, or the like, as a main component. The solder resist layers 65 and 75 may include, for example, a filler such as silica or alumina.

The wiring layer 60 is stacked on the lower surface of the core layer 51. The wiring layer 60 is electrically connected to the wiring layer 70 via the through-electrode 52. The insulation layer 61 is stacked on the lower surface of the core layer 51 to cover the wiring layer 60. The wiring layer 62 is formed on the lower surface of the insulation layer 61. The wiring layer 62 is, for example, formed integrally with a via wiring extending through the insulation layer 61 in the thickness-wise direction and electrically connected to the wiring layer 60 by the via wiring. The insulation layer 63 is stacked on the lower surface of the insulation layer 61 to cover the wiring layer 62. The wiring layer 64 is formed on the lower surface of the insulation layer 63. The wiring layer 64 is formed in the lowermost layer of the wiring substrate 50. The wiring layer 64 is, for example, formed integrally with a via wiring extending through the insulation layer 63 in the thickness-wise direction and electrically connected to the wiring layer 62 by the via wiring.

The thickness of each of the wiring layers 60, 62, and 64 may be, for example, approximately 15 μm to 35 μm. The thickness of each of the insulation layers 61 and 63 may be, for example, approximately 20 μm to 45 μm.

The solder resist layer 65 is the outermost insulation layer, which is the outermost layer (in the present embodiment, the lowermost layer) of the wiring substrate 50. The solder resist layer 65 is formed on the lower surface of the insulation layer 63 so as to cover the wiring layer 64, which is the lowermost layer. The solder resist layer 65 includes openings 65X that expose portions of the wiring layer 64, which is the lowermost layer, as external connection pads 64P. The external connection pads 34P are connected to external connection terminals used when mounting the stacked wiring substrate 2 on a mount substrate such as a motherboard.

The wiring layer 70 is stacked on the upper surface of the core layer 51. The wiring layer 70 is electrically connected to the wiring layer 60 via the through-electrode 52. The insulation layer 71 is stacked on the upper surface of the core layer 51 to cover the wiring layer 70. The wiring layer 72 is stacked on the upper surface of the insulation layer 71. The wiring layer 72 is, for example, formed integrally with a via wiring extending through the insulation layer 71 in the thickness-wise direction and electrically connected to the wiring layer 70 by the via wiring. The insulation layer 73 is stacked on the upper surface of the insulation layer 71 to cover the wiring layer 72. The wiring layer 74 is stacked on the upper surface of the insulation layer 73. The wiring layer 74 is formed in the uppermost layer of the wiring substrate 50. The wiring layer 74 serves as an external connection terminal for electrical connection to another wiring substrate, or the wiring substrate 10. The wiring layer 74 is, for example, formed integrally with a via wiring extending through the insulation layer 73 in the thickness-wise direction and electrically connected to the wiring layer 72 by the via wiring. For example, multiple wiring patterns of the wiring layer 74 are arranged to respectively face multiple wiring patterns of the wiring layer 20 of the wiring substrate 10.

The wiring layer 74 may have any planar shape and any planar size. The planar shape of the wiring layer 74 is, for example, circular. The diameter of the wiring layer 74 may be, for example, approximately 70 μm to 85 μm.

The solder resist layer 75 is the outermost insulation layer, which is the outermost layer (in the present embodiment, the uppermost layer) of the wiring substrate 50. The solder resist layer 75 is formed on the upper surface of the insulation layer 73. The solder resist layer 75 is stacked on the upper surface of the insulation layer 73 so as to expose the wiring layer 74. The solder resist layer 75 has an opening 75X extending through the solder resist layer 75 in the thickness-wise direction and exposing the wiring layer 74 and part of the upper surface of the insulation layer 73. For example, the opening 75X is formed to overlap a mount region in which the wiring substrate 10 is mounted in plan view. The opening 75X exposes the upper surface of the insulation layer 73 and the wiring layer 74 in the mount region. In other words, the solder resist layer 75 surrounds the mount region in plan view.

The wiring substrate 50 may have any planar shape and any planar size. The wiring substrate 50 is greater in size than the wiring substrate 10 in plan view. The planar shape of the wiring substrate 50 may be, for example, quadrilateral and have a size of approximately 60 mm×60 mm to 80 mm×80 mm.

The wiring substrate 10 is mounted on the upper surface of the wiring substrate 50. The wiring substrate 10 is mounted on, for example, the wiring layer 74 of the wiring substrate 50. For example, the wiring layer 74 of the wiring substrate 50 and the wiring layer 20 of the wiring substrate 10 are bonded to each other by a solder layer 81. The solder layer 81 is bonded to the upper and side surfaces of the wiring layer 74 and to the lower surface of the wiring layer 20. The material of the solder layer 81 may be, for example, an alloy containing lead (Pb), an alloy of tin (Sn) and Au, an alloy of Sn and Cu, an alloy of Sn and silver (Ag), an alloy of Sn, Ag, and Cu, or the like.

### Structure of Underfill Resin 85

The underfill resin 85 fills the gap between the wiring substrate 50 and the wiring substrate 10. The underfill resin 85 fills the gap between the upper surface of the insulation layer 73 exposed in the opening 75X and the lower surface of the insulation layer 21 in the wiring substrate 10. The material of the underfill resin 85 may be, for example, an insulating resin such as epoxy resin.

As described above, the wiring substrate 10, which has a wiring structure having a relatively high wiring density, is mounted on the wiring substrate 50, which has a wiring structure having a relatively low wiring density. Thus, the stacked wiring substrate 2 is readily manufactured and allows for mounting of electronic components such as semiconductor chips with a high wiring density.

### Structure of Semiconductor Chip 91

Each semiconductor chip 91 includes, for example, electrode pads 92 formed on a circuit formation surface (lower surface) of the semiconductor chip 91. The semiconductor chip 91 is flip-chip mounted on the wiring substrate 10. The electrode pads 92 of the semiconductor chip 91 are, for example, electrically connected to the pads P1 of the wiring substrate 10 by bumps 93. Thus, the semiconductor chip 91 is electrically connected to the wiring layer 37 by the electrode pads 92 and the bumps 93.

The semiconductor chip 91 may be, for example, a logic chip such as a central processing unit (CPU) chip or a graphics processing unit (GPU) chip.

Further, the semiconductor chip 91 may be, for example, a memory chip such as a dynamic random access memory (DRAM) chip, a static random access memory (SRAM) chip, or a flash memory chip.

When mounting multiple semiconductor chips 91 on the wiring substrate 10, a logic chip may be mounted in combination with a memory chip on the wiring substrate 10. The semiconductor chips 91 may have the same size or may have different sizes.

The bumps 93 may be, for example, gold bumps or solder bumps. The material of the solder bumps may be, for example, an alloy including Pb, an alloy of Sn and Au, an alloy of Sn and Cu, an alloy of Sn and Ag, or an alloy of Sn, Ag, and Cu.

The gaps between the wiring substrate 10 and the semiconductor chip 91 are filled with the underfill resin 95. The material of the underfill resin 95 may be, for example, an insulating resin such as an epoxy resin.

In the semiconductor device 1, the semiconductor chips 91 are mounted on the wiring substrate 10 having a wiring structure with a high wiring density. The semiconductor chips 91 are readily signal-connected by the wiring structure with a high wiring density.

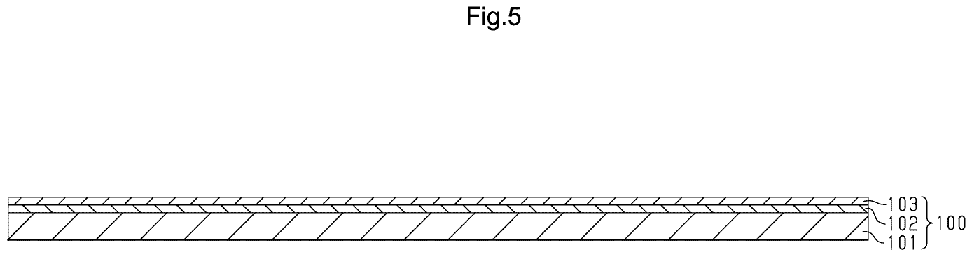

Method for Manufacturing the Wiring Substrate 10 A method for manufacturing the wiring substrate 10 will now be described with reference to FIGS. 5 to 21. To simplify illustration, elements that will consequently become final elements of the wiring substrate 10 are given the same reference characters as the final elements.

In the step illustrated in FIG. 5, a support 100 is prepared. The support 100 has, for example, a structure in which a metal foil 102 and a metal film 103 are sequentially formed on the upper surface of a base 101. The base 101 is, for example, a prepreg obtained by impregnating a reinforcement member such as a woven cloth or a non-woven cloth of glass or aramid with a thermosetting resin such as an epoxy resin or a polyimide resin. The metal foil 102 is, for example, a copper foil. The metal film 103 is, for example, a Ni plating film. The material of the metal foil 102 is not limited to copper and may be a metal other than copper. The material of the metal film 103 may be a metal other than nickel as long as the material is conductive and may be selectively etched and removed from the wiring layer 20 (refer to FIG. 1) in a subsequent step.

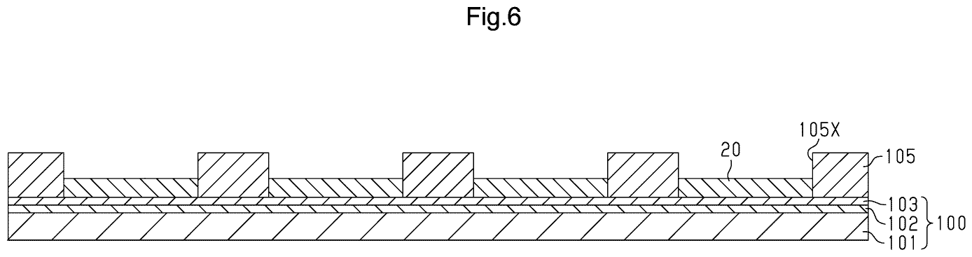

In the step illustrated in FIG. 6, a resist layer 105 having an opening pattern 105X is formed on the upper surface of the metal film 103 of the support 100. The opening pattern 105X exposes portions of the upper surface of the metal film 103 that correspond to the region where the wiring layer 20 is formed. The material of the resist layer 105 may be, for example, a material that resists plating in the plating process performed in the following step. The material of the resist layer 105 may be, for example, a photosensitive dry film resist or a liquid photoresist (e.g., dry film resist or liquid resist of novolac resin or acrylic resin). In an example in which a photosensitive dry film resist is used, the upper surface of the metal film 103 is laminated with a dry film by thermocompression bonding, and then the dry film is patterned by photolithography to form the resist layer 105 having the opening pattern 105X. When a liquid photoresist is used, the resist layer 105 may also be formed by the same steps.

Subsequently, electrolytic plating is performed on the metal film 103 so that the resist layer 105 serves as a plating mask and the metal film 103 serves as a plating power feeding layer. That is, electrolytic plating (in this embodiment, electrolytic Cu plating) is performed on the upper surface of the metal film 103 exposed in the opening pattern 105X of the resist layer 105. As a result of the present step, the wiring layer 20 is formed on the upper surface of the metal film 103 exposed from the opening pattern 105X.

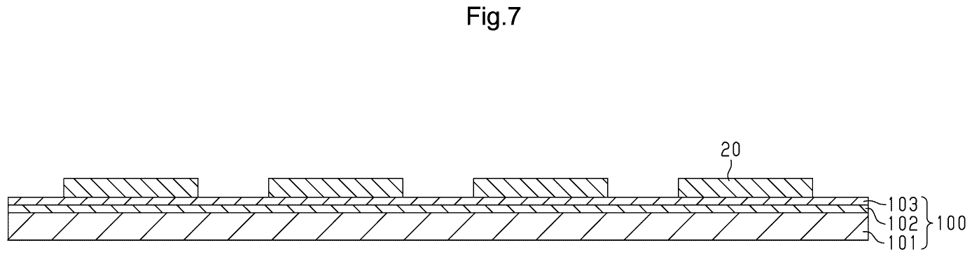

In the step illustrated in FIG. 7, the resist layer 105 illustrated in FIG. 6 is removed using an alkaline stripping solution (e.g., organic amine stripping solution, caustic soda, acetone, ethanol, or the like).

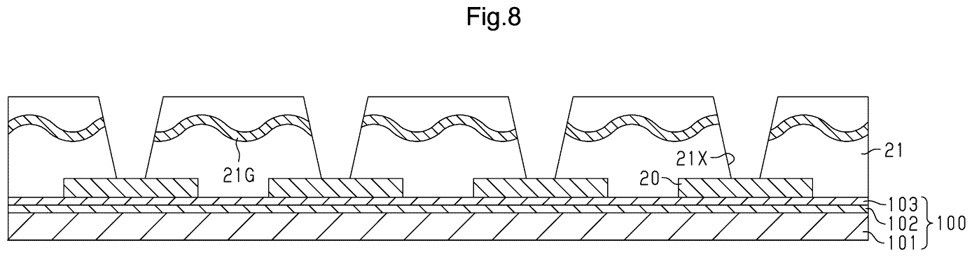

In the step illustrated in FIG. 8, the insulation layer 21 is formed on the upper surface of the metal film 103 and covers the wiring layer 20. For example, when a resin film is used as the insulation layer 21, the upper surface of the metal film 103 is laminated with the resin film. The resin film is heated at a curing temperature or higher (e.g., approximately 130° C. to 200° C.) while being pressed so that the resin film is cured to form the insulation layer 21. The resin film may be, for example, a film of a thermosetting resin including an epoxy resin as a main component.

Subsequently, through holes 21X are formed in given locations of the insulation layer 21 to expose part of the upper surface of the wiring layer 20. The through holes 21X may be formed by, for example, laser drilling using CO₂ laser, UV-YAG laser, or the like.

In a case in which the through holes 21X are formed by laser drilling, a desmear process is performed to remove resin smears from the surface of the wiring layer 20 exposed at the bottom of the through holes 21X.

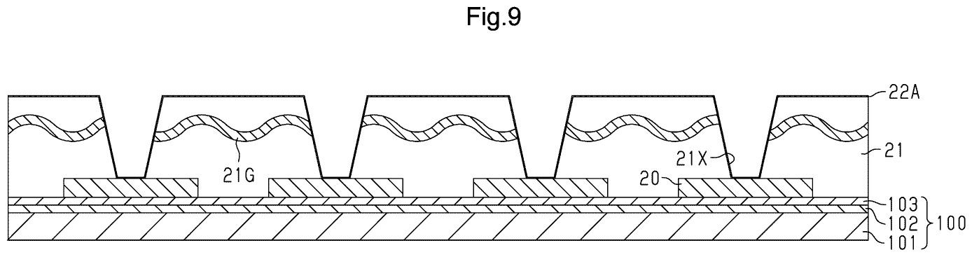

In the step illustrated in FIG. 9, the seed layer 22A is formed to cover the entire upper surface of the insulation layer 21, the entire wall surface of each through hole 21X, and the entire upper surface of the wiring layer 20 exposed at the bottom of the through hole 21X. The seed layer 22A may be formed by, for example, sputtering or electroless plating.

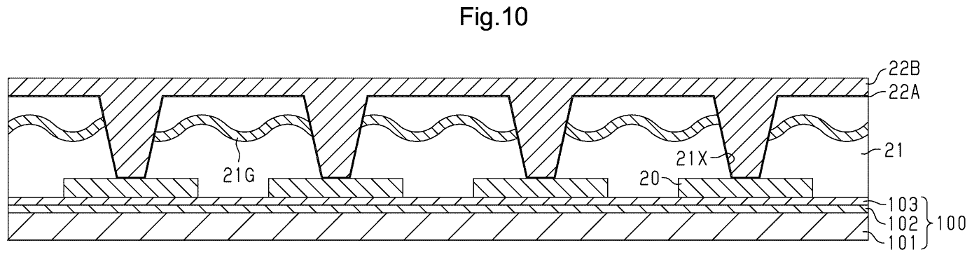

Subsequently, in the step illustrated in FIG. 10, electrolytic plating (in this embodiment, electrolytic Cu plating) is performed so that the seed layer 22A serves as a plating power feeding layer. As a result, the metal layer 22B fills the through holes 21X on an inner side of the seed layer 22A and covers the entire upper surface of the seed layer 22A formed on the upper surface of the insulation layer 21.

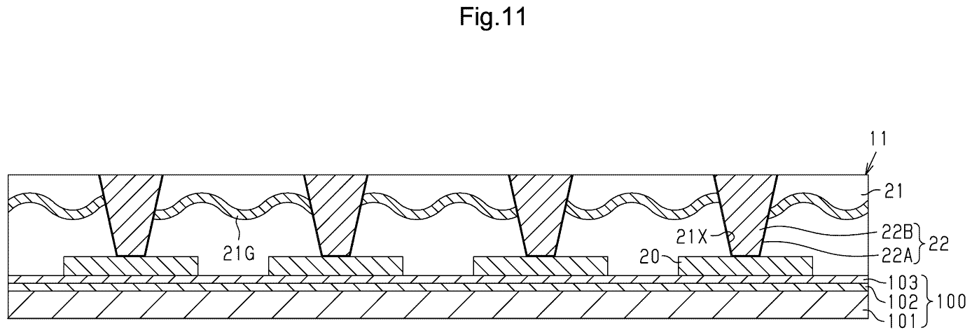

In the step illustrated in FIG. 11, for example, chemical mechanical polishing (CMP) is performed to polish the metal layer 22B protruding from the upper surface of the insulation layer 21 and part of the upper surface of the insulation layer 21.

As a result, the wiring layer 22 including the seed layer 22A and the metal layer 22B is formed in the through holes 21X, and the upper end surface of the wiring layer 22 is flush with the upper surface of the insulation layer 21. In addition, the polishing of part of the upper surface of the insulation layer 21 smoothens the upper surface of the insulation layer 21. For example, a roughness value Ra of the upper surface of the insulation layer 21 before the polishing may be approximately 300 nm to 400 nm, and a roughness value Ra of the upper surface of the insulation layer 21 after the polishing may be approximately 15 nm to 40 nm. As a result of the polishing in this step, the upper surface of the insulation layer 21 and the upper end surface of the wiring layer 22 include polished surfaces.

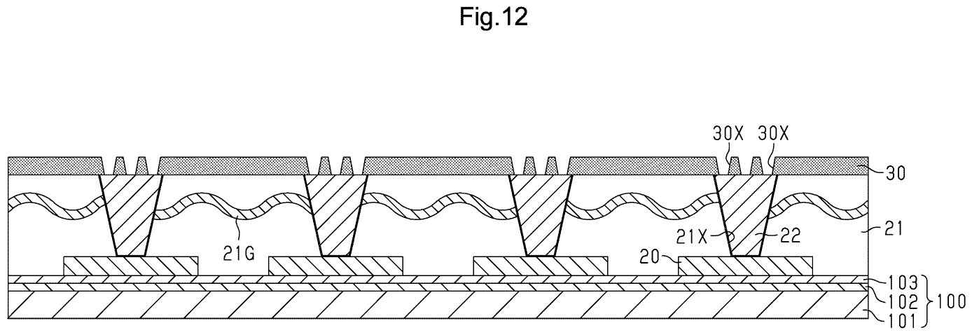

In the step illustrated in FIG. 12, the insulation layer 30 is formed on the upper surface of the insulation layer 21 to cover the entire upper surface of the insulation layer 21 and the entire upper end surface of the wiring layer 22. Then, the through holes 30X, which extend through the insulation layer 30 in the thickness-wise direction and expose part of the upper end surface of the wiring layer 22, are formed at given locations of the insulation layer 30. Multiple through holes 30X are formed for each connection via of the wiring layer 22.

When using a resin film as the insulation layer 30, for example, the upper surface of the insulation layer 21 is laminated with a resin film through thermocompression bonding, and then the resin film is patterned by photolithography to form the insulation layer 30.

Alternatively, the upper surface of the insulation layer 21 is coated with a liquid or paste of insulating resin by spin coating or the like. Then, the insulating resin is patterned by photolithography to form the insulation layer 30.

Through the above manufacturing steps, the first wiring structure 11 is formed on the support 100.

The upper surface of the insulation layer 30 formed from such an insulating resin, the main component of which is photosensitive resin, may have a roughness value Ra of, for example, approximately 2 nm to 10 nm. For example, the upper surface of the insulation layer 30 has a smaller surface roughness than the upper surface (polished surface) of the insulation layer 21.

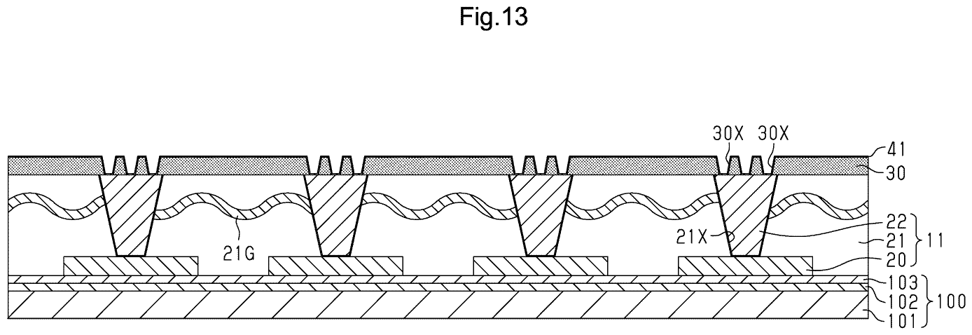

In the step illustrated in FIG. 13, the seed layer 41 is formed to cover the entire upper surface of the insulation layer 30, the entire wall surface of each through hole 30X, and the entire upper end surface of the wiring layer 22 exposed at the bottom of the through hole 30X. The seed layer 41 may be formed by, for example, sputtering or electroless plating.

In an example in which the seed layer 41 is formed by sputtering, titanium is first sputtered and deposited on the upper surface of the insulation layer 30 and the wall surfaces of the through holes 30X to form a Ti layer that covers the upper surface of the insulation layer 30 and the wall surfaces of the through holes 30X. Then, copper is sputtered and deposited on the Ti layer to form a Cu layer. This forms the seed layer 41 having a double-layered (Ti layer/Cu layer) structure. In another example in which the seed layer 41 is formed by electroless plating, electroless copper plating may be performed to form the seed layer 41 having a Cu layer (single-layer structure).

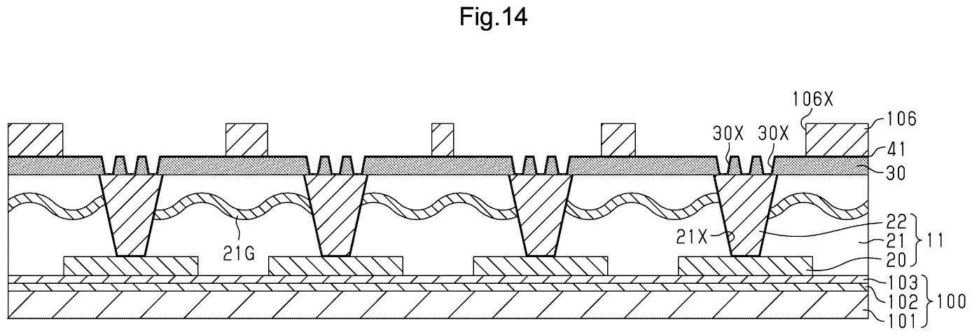

In the step illustrated in FIG. 14, a resist layer 106 having an opening pattern 106X at a given location is formed on the seed layer 41. The opening pattern 106X exposes a portion of the seed layer 41 corresponding to a region in which the wiring layer 31 (refer to FIG. 1) is formed. The material of the resist layer 106 may be, for example, a material that resists plating in the plating process performed in the following step. The material of the resist layer 106 may be, for example, the same as the material of the resist layer 105 illustrated in FIG. 6. The resist layer 106 may be formed, for example, by the same process as the resist layer 105 illustrated in FIG. 6.

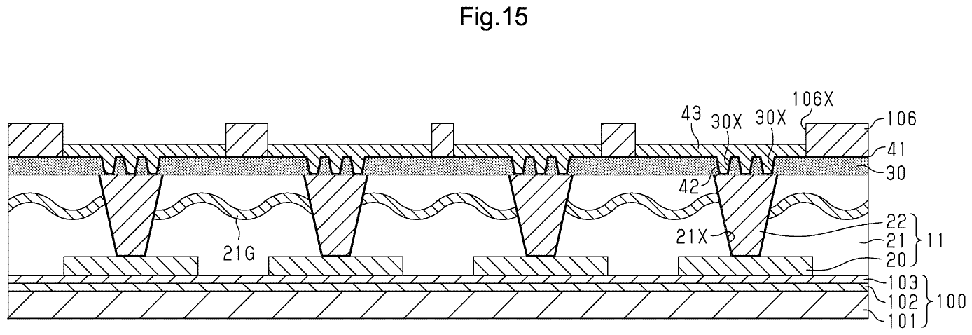

In the step illustrated in FIG. 15, electrolytic plating (in this embodiment, electrolytic Cu plating) is performed on the seed layer 41 exposed from the opening pattern 106X of the resist layer 106 so that the resist layer 106 serves as a plating mask and the seed layer 41 serves as a plating power feeding layer. As a result, the metal layer 42 is formed to fill the through holes 30X on an inner side of the seed layer 41, and the metal layer 43 is formed on the seed layer 41 formed on the upper surface of the insulation layer 30.

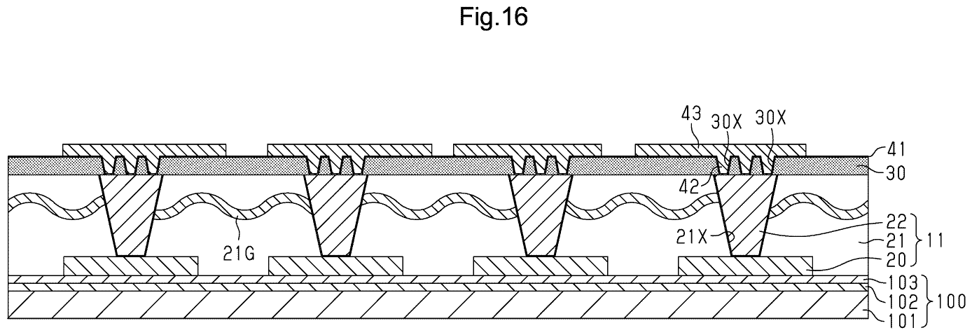

In the step illustrated in FIG. 16, the resist layer 106 illustrated in FIG. 15 is removed by an alkali stripping solution.

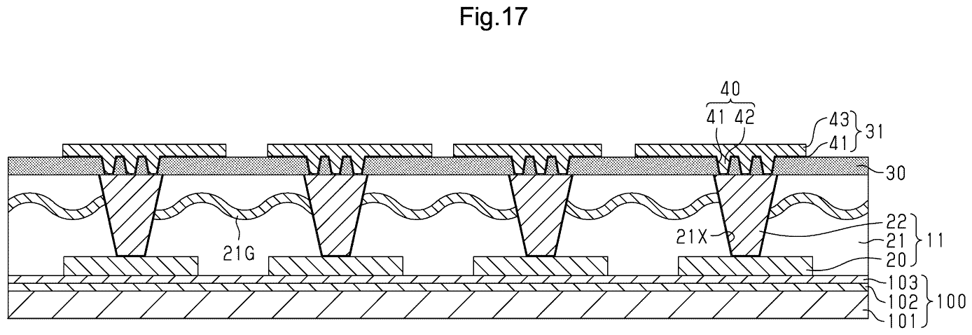

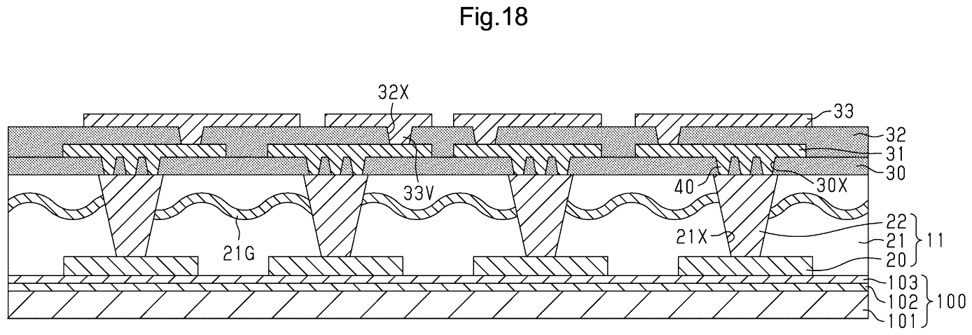

In the step illustrated in FIG. 17, unwanted portions of the seed layer 41 are removed by etching using the metal layers 42 and 43 as etching masks. For example, when the seed layer 41 is formed of a Ti layer and a Cu layer, unwanted portions of the Cu layer are removed by wet etching using a sulfuric acid-hydrogen peroxide-based etchant. Then, for example, unwanted portions of the Ti layer are removed by dry etching using an etching gas such as CF4 or wet etching using a KOH-based etchant. As a result of this step, the via wirings 40 are formed in the through holes 30X and include the seed layer 41 and the metal layer 42 formed in the through holes 30X. In addition, the wiring layer 31 is formed on the upper surface of the insulation layer 30 and includes the seed layer 41 and the metal layer 43 formed on the upper surface of the insulation layer 30. As described above, the via wirings 40 and the wiring layer 31 are formed by a semi-additive process. FIGS. 18 to 22 illustrate the via wirings 40 and the wiring layer 31 instead of illustrating them as the seed layer 41 and the metal layers 42 and 43.

In the step illustrated in FIG. 18, steps similar to those illustrated in FIGS. 12 to 17 are performed to stack the insulation layer 32 and the wiring layer 33 on the upper surface of the insulation layer 30.

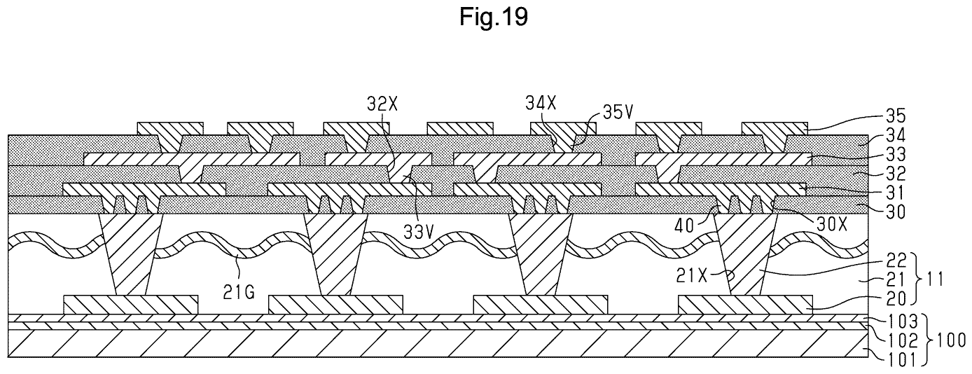

In the step illustrated in FIG. 19, steps similar to those illustrated in FIGS. 12 to 17 are performed to stack the insulation layer 34 and the wiring layer 35 on the upper surface of the insulation layer 32.

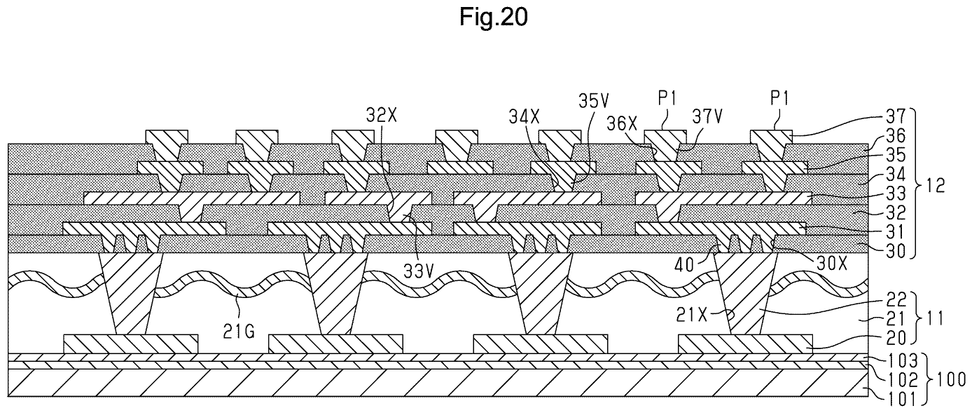

In the step illustrated in FIG. 20, steps similar to those illustrated in FIGS. 12 to 17 are performed to stack the insulation layer 36 and the wiring layer 37 on the upper surface of the insulation layer 34.

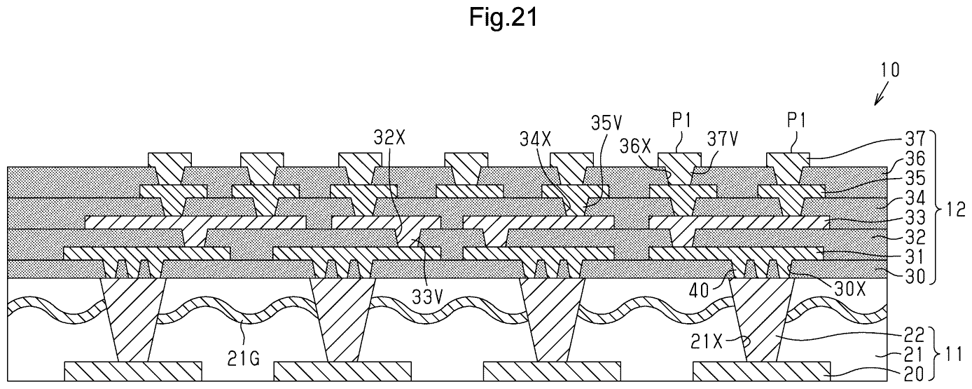

Then, the support 100 is removed. For example, the base 101 is first removed from the support 100. The base 101 is, for example, mechanically separated from the metal foil 102. Subsequently, the metal foil 102 is removed. The metal foil 102 is, for example, mechanically separated from the metal film 103. For example, the metal foil 102 is selectively removed by etching from the metal film 103. Next, the metal film 103 is removed. For example, the metal film 103 is selectively removed by etching from the wiring layer 20. As a result, as illustrated in FIG. 21, the lower surface of the wiring layer 20 and the lower surface of the insulation layer 21 are exposed to the exterior. In this step, the lower surface of the wiring layer 20 and the lower surface of the insulation layer 21, which were in contact with the upper surface of the metal film 103 (refer to FIG. 20), are shaped in conformance with the upper surface (in the present embodiment, flat surface) of the metal film 103. Hence, the lower surface of the wiring layer 20 is flush with the lower surface of the insulation layer 21.

The wiring substrate 10 of the present embodiment is manufactured through the manufacturing steps described above.

### Method for Manufacturing Stacked Wiring Substrate 2

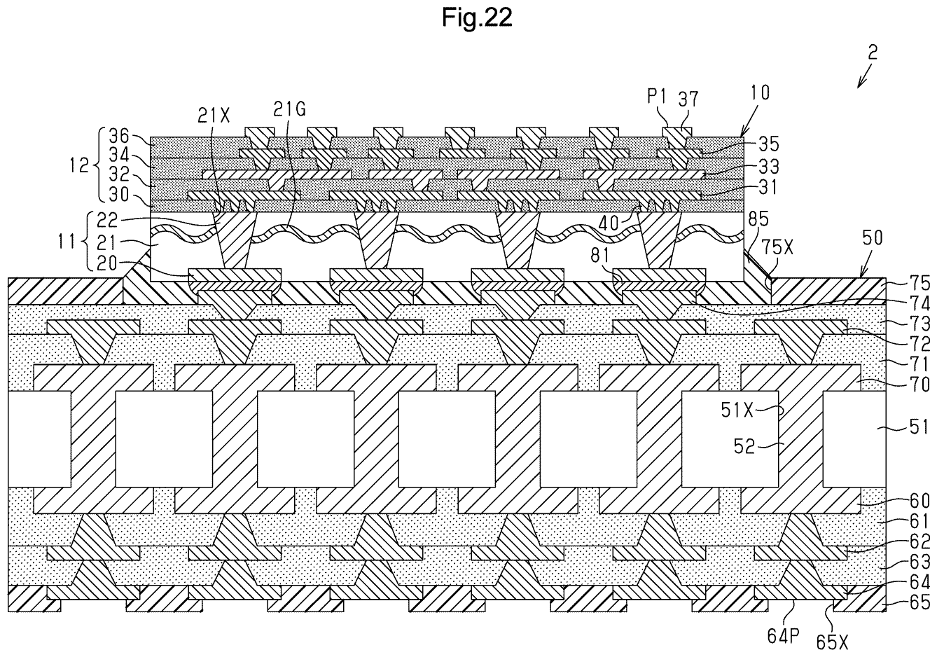

A method of manufacturing the stacked wiring substrate 2 will now be described with reference to FIG. 22.

In the step illustrated in FIG. 22, the wiring substrate 50 is manufactured. The wiring substrate 50 may be manufactured by a known manufacturing process. Thus, such a process will not be described in detail.

The wiring substrate 10 is mounted on the wiring substrate 50. For example, the wiring layer 20 of the wiring substrate 10 is bonded to the wiring layer 74 of the wiring substrate 50 by the solder layer 81. Subsequently, the gap between the wiring substrate 50 and the wiring substrate 10, which are bonded to each other, is filled with the underfill resin 85. The underfill resin 85 is cured.

The stacked wiring substrate 2 of the present embodiment is manufactured through the manufacturing steps described above.

### Operation and Effect of the Present Embodiment

The operation and advantages of the present embodiment will now be described.

(1) The wiring substrate 10 includes a first wiring structure 11 and a second wiring structure 12 that is formed on the upper surface of the first wiring structure 11 and has a higher wiring density than the first wiring structure 11. The first wiring structure 11 includes a wiring layer 20, an insulation layer 21 covering the wiring layer 20, and a wiring layer 22 extending through the insulation layer 21 in the thickness-wise direction and being electrically connected to the wiring layer 20. The wiring layer 22 includes an upper end surface exposed from the upper surface of the insulation layer 21. The second wiring structure 12 includes an insulation layer 30 formed on the upper surface of the insulation layer 21, multiple through holes 30X extending through the insulation layer 30 in the thickness-wise direction to expose part of the upper end surface of the wiring layer 22, and multiple via wirings 40 respectively filling the through holes 30X. The second wiring structure 12 includes a wiring layer 31 formed on the upper surface of the insulation layer 30 and electrically connected to the wiring layer 22 by the via wirings 40. The content ratio of a filler in the insulation layer 30 is lower than the content ratio of a filler in the insulation layer 21.

With this structure, the lowermost insulation layer 30 of the second wiring structure 12, which has a high-density wiring structure, is formed on the upper surface of the insulation layer 21 of the first wiring structure 11, which has a low-density wiring structure. The lowermost wiring layer 31 of the second wiring structure 12 is formed on the upper surface of the insulation layer 30. The lowermost wiring layer 31 is electrically connected to the wiring layer 22 by the via wirings 40 extending through the lowermost insulation layer 30 in the thickness-wise direction. Thus, the wiring layer 31, which is fine wiring, is not formed on the upper surface of the insulation layer 21 having a relatively high filler content ratio and instead is formed on the upper surface of the insulation layer 30 having a lower filler content ratio than the insulation layer 21. This limits wiring separation and wiring delamination caused by filler detachment.

When forming the wiring layer 31, in the step of removing unwanted portions of the seed layer, as the unwanted portions of the seed layer are completely removed to improve the insulation reliability, the insulation layer located under the wiring layer 31 is also partially etched and removed. In a structure in which the wiring layer 31 is formed on the upper surface of the insulation layer 21, which has a relatively high filler content ratio, the upper surface of the insulation layer 21 is partially etched and removed. In this structure, if the upper surface of the insulation layer 21 is overly etched, filler is detached from the insulation layer 21. This cuts into a side surface of the insulation layer 21 located under the wiring layer 31. As a result, the insulation layer 21 located under the wiring layer 31 is reduced in thickness, and a gap is formed between the wiring layer 31 and the insulation layer 21. That is, wiring separation has occurred.

In this regard, in the wiring substrate 10 of the present embodiment, the lowermost wiring layer 31 of the second wiring structure 12 is formed on the upper surface of the insulation layer 30, which has a lower filler content than the insulation layer 21. This limits reduction in thickness of the insulation layer 30 located under the wiring layer 31 caused by filler detachment. Accordingly, wiring separation and wiring delamination caused by the filler detachment is limited. Thus, the wiring layer 31, which is fine wiring, is stably formed. This improves the reliability of electrical connection between the wiring layer 31 having the high-density wiring structure and the wiring layer 22 having the low-density wiring structure.

(2) The wiring layer 31 is electrically connected to the wiring layer 22 through the via wirings 40, which are smaller in planar size than each connection via of the wiring layer 22. That is, multiple via wirings 40 having a relatively small diameter are connected to each connection via of the wiring layer 22. With this structure, the aspect ratio of the through hole 30X is decreased as compared with a structure in which a single via wiring having the same planar size as a single connection via of the wiring layer 22 is connected to the connection via of the wiring layer 22. Thus, the through hole 30X is filled with the via wiring 40 in an improved manner. This improves the flatness of the upper surface of the wiring layer 31 connected to the via wirings 40.

(3) The cross-sectional area of the conductor in the via wirings 40, which connect the wiring layer 22 and the wiring layer 31, is increased as compared with a structure in which a single via wiring 40 having a relatively small diameter is connected to each connection via of the wiring layer 22. This avoids signal deterioration caused by a decrease in the cross-sectional area of the conductor in the via wirings 40.

(4) The insulation layer 30 includes a photosensitive resin as a main component. This structure allows the upper surface of the insulation layer 30 to have a smaller surface roughness than the upper surface (polished surface) of the insulation layer 21. Thus, the wiring layer 31, which is fine wiring, is suitably formed on the upper surface of the insulation layer 21.

### Modified Examples

The embodiment described above may be modified as follows. The embodiment and the following modified examples may be combined as long as the combined modifications remain technically consistent with each other.

In the embodiment, five via wirings 40 are connected to each connection via of the wiring layer 22. However, the number of via wirings 40 connected to each connection via of the wiring layer 22 is not particularly limited. For example, two to four via wirings 40 may be connected to each connection via of the wiring layer 22. Six or more via wirings 40 may be connected to each connection via of the wiring layer 22.

In the embodiment, the multiple via wirings 40 are arranged in a cross in plan view. However, the arrangement of the via wirings 40 is not limited to that described in the embodiment.

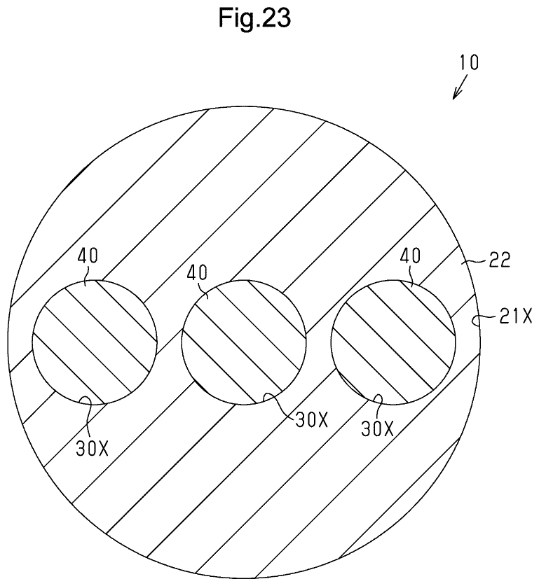

In an example, as illustrated in FIG. 23, multiple via wirings 40 may be arranged in only one direction (in the present embodiment, the horizontal direction in the drawing) in plan view. In this modified example, three via wirings 40 are arranged in a line in the horizontal direction in the drawing in plan view.

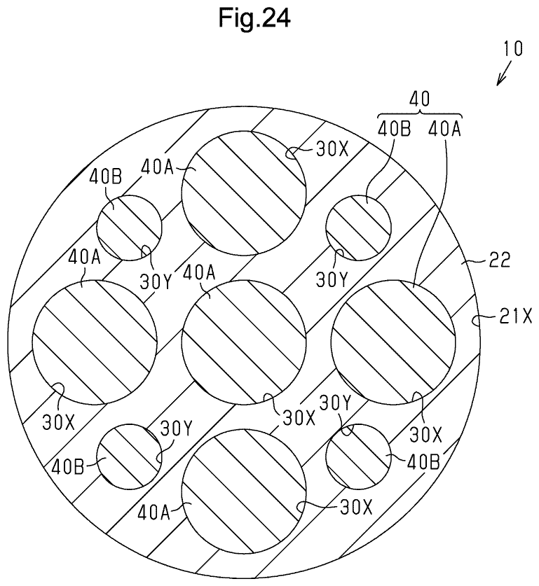

In an example, as illustrated in FIG. 24, multiple via wirings 40 may be arranged in a matrix in plan view. In this modified example, nine via wirings 40 are arranged in a 3×3 matrix in plan view.

In the embodiment, the via wirings 40 have the same planar size. However, there is no limit to such a configuration.

In an example, as illustrated in FIG. 24, the via wirings 40 may include different types of via wirings 40 differing in planar size. In this modified example, the via wirings 40 include a first via wiring 40A and a second via wiring 40B that is smaller in planar size than the first via wiring 40A. In this modified example, the via wirings 40 include five first via wirings 40A and four second via wirings 40B. Each first via wiring 40A is formed to fill a through hole 30X. Each second via wiring 40B fills a through hole 30Y. In this example, the through hole 30Y has a smaller diameter than the through hole 30X.

In this structure, the second via wiring 40B has a smaller planar size than the first via wiring 40A. Thus, the second via wiring 40B having a relatively small diameter is suitably formed in a space where the first via wiring 40A cannot be formed. This allows for increases in the cross-sectional area of the conductor in the via wirings 40, thereby further limiting signal deterioration.

In the embodiment, the structure of the wiring substrate 10 may be changed.

In the embodiment, the number of wiring layers, the number of insulation layers, and the layout of wirings in the first wiring structure 11 may be changed in various manners.

In the embodiment, the insulation layer 21 may be changed to an insulation layer that does not include the reinforcement member 21G.

In the embodiment, the upper end surface of the wiring layer 22 is flush with the upper surface of the insulation layer 21. However, there is no limit to such a configuration.

In an example, the upper end surface of the wiring layer 22 may be recessed from the upper surface of the insulation layer 21 toward the wiring layer 20 (in the present embodiment, downward). In an example, the upper end surface of the wiring layer 22 may be formed so as to protrude toward the second wiring structure 12 (in the present embodiment, upward) from the upper surface of the insulation layer 21.

In the embodiment, the lower surface of the wiring layer 20 is flush with the lower surface of the insulation layer 21. However, there is no limit to such a configuration. In an example, the lower surface of the wiring layer 20 may be recessed toward the wiring layer 22 (in the present embodiment, upward) from the lower surface of the insulation layer 21. In an example, the lower surface of the wiring layer 20 may protrude downward from the lower surface of the insulation layer 21.

In the embodiment, the number of wiring layers, the number of insulation layers, and the layout of wirings in the second wiring structure 12 may be changed in various manners.

In the embodiment, the via wirings 33V do not overlap the via wirings 40 in plan view. However, there is no limit to such a configuration. For example, the via wirings 33V may be arranged to overlap the via wirings 40 in plan view.

In the above embodiment, the insulation layers 30, 32, 34, and 36 in the second wiring structure 12 include a photosensitive resin as a main component. Instead, for example, the insulation layers 30, 32, 34, and 36 may include a non-photosensitive resin as a main component. In this case, the through holes 30X, 32X, 34X, and 36X are formed by, for example, laser drilling that uses an excimer laser suitable for fine machining.

In the embodiment, the structure of the stacked wiring substrate 2 may be changed.

In the embodiment, a single wiring substrate 10 is mounted on a single wiring substrate 50. However, there is no limit to such a configuration. In an example, multiple wiring substrates 10 may be mounted on a single wiring substrate 50.

In the embodiment, the number of wiring layers, the number of insulation layers, and the layout of wirings in the wiring substrate 50 may be changed in various manners.

In the embodiment, the wiring layers 70 and 60, which are located at the upper and lower sides of the core layer 51, are electrically connected to each other via the through-electrodes 52 filling the through holes 51X in the core layer 51. Alternatively, for example, the upper and lower wiring layers 70 and 60, which are located at the upper and lower sides of the core layer 51, may be electrically connected to each other via a through hole plating layer formed on the wall of the through hole 51X. In this case, a resin may fill a space of the through hole 51X located at an inner side of the through hole plating layer.

In the embodiment, the solder resist layers 65 and 75 are used as an example of a protective insulation layer that is the outermost layer of the wiring substrate 50. However, a protective insulation layer may be formed by various types of photosensitive insulative resin.

In the embodiment, the solder resist layers 65 and 75 may be omitted.

In the semiconductor device 1 of the embodiment, the semiconductor chip 91 is mounted on the stacked wiring substrate 2. Alternatively, for example, instead of the semiconductor chip 91, a chip component such as a chip capacitor, a chip resistor, or a chip inductor, or an electronic component other than a semiconductor chip, such as a crystal oscillator, may be mounted on the stacked wiring substrate 2.

In addition, the mounting of a semiconductor chip, a chip component, and an electronic component such as a crystal oscillator may be changed in various manners. The mounting of an electronic component may be, for example, flip-chip mounting, wire bonding mounting, solder mounting, or a combination of these.

In the above embodiment, the present disclosure is embodied in a method for manufacturing a single substrate. Instead, the present disclosure may be embodied in a method for manufacturing a batch of substrates.

### CLAUSES

This disclosure further encompasses the following embodiments.
1. A method for manufacturing a wiring substrate, the method including:
forming a first wiring structure; and
forming a second wiring structure on an upper surface of the first wiring structure, the second wiring structure having a wiring density that is higher than that of the first wiring structure, in which
the forming a first wiring structure includes
   forming a first wiring layer,
   forming a first insulation layer that covers the first wiring layer, and
   forming a second wiring layer that extends through the first insulation layer in a thickness-wise direction and is electrically connected to the first wiring layer, the second wiring layer including an upper end surface exposed from an
   upper surface of the first insulation layer,
   the forming a second wiring structure includes
      forming a second insulation layer that covers the upper surface of the first insulation layer and the upper end surface of the second wiring layer,
      forming multiple through holes that extend through the second insulation layer in the thickness-wise direction and expose part of the upper end surface of the second wiring layer, and
      forming multiple via wirings that respectively fill the through holes and
   forming a third wiring layer on an upper surface of the second insulation layer that is electrically connected to the second wiring layer by the via wirings, and
   a content ratio of filler in the second insulation layer is lower than a content ratio of filler in the first insulation layer.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A wiring substrate, comprising:
a first wiring structure; and
a second wiring structure formed on an upper surface of the first wiring structure and having a wiring density that is higher than that of the first wiring structure, wherein
the first wiring structure includes
a first wiring layer,
a first insulation layer covering the first wiring layer, and
a second wiring layer extending through the first insulation layer in a thickness-wise direction and electrically connected to the first wiring layer, the second wiring layer including an upper end surface exposed from an upper surface of the first insulation layer,
the second wiring structure includes
a second insulation layer formed on the upper surface of the first insulation layer,
multiple through holes extending through the second insulation layer in the thickness-wise direction and exposing part of the upper end surface of the second wiring layer,
multiple via wirings respectively filling the through holes, and
a third wiring layer formed on an upper surface of the second insulation
layer and electrically connected to the second wiring layer by the via wirings, and a content ratio of filler in the second insulation layer is lower than a content ratio of filler in the first insulation layer.

2. The wiring substrate according to claim 1, wherein
each of the via wirings is smaller in planar size than the second wiring layer, and
each of the via wirings includes
a seed layer covering a wall surface of one of the through holes and the upper end surface of the second wiring layer exposed at a bottom of the one of the through holes, and
a metal layer filling the one of the through holes on an inner side of the seed layer.

3. The wiring substrate according to claim 1, wherein
in plan view, the second wiring layer is circular,
in plan view, each of the via wirings is circular, and
in plan view, the via wirings are arranged in a cross.

4. The wiring substrate according to claim 1, wherein the via wirings include a first via wiring and a second via wiring that is smaller in planar size than the first via wiring.

5. The wiring substrate according to claim 1, wherein
the first insulation layer includes a non-photosensitive resin as a main component, and
the second insulation layer includes a photosensitive resin as a main component.

6. The wiring substrate according to claim 1, wherein
the first wiring structure includes only the first wiring layer, the first insulation layer, and the second wiring layer, and
the upper end surface of the second wiring layer is flush with the upper surface of the first insulation layer.

7. The wiring substrate according to claim 1, wherein
the second wiring layer is a connection via located immediately below the via wirings, and
two or more of the via wirings are arranged side by side in at least one direction on an upper surface of the connection via.

8. The wiring substrate according to claim 7, wherein
three of the via wirings are arranged side by side in the at least one direction on the upper surface of the connection via.

9. The wiring substrate according to claim 7, wherein
a number of the via wirings arranged on the upper surface of the connection via is five or more.

10. A stacked wiring substrate, comprising:
the wiring substrate according to claim 1, defining a first wiring substrate; and
a second wiring substrate including an upper surface on which the first wiring substrate is mounted, wherein
the second wiring substrate includes
a third wiring structure having a wiring density that is lower than that of the second wiring structure, and
a fourth wiring layer formed as an uppermost wiring layer of the third wiring structure and connected to the first wiring layer.

11. A semiconductor device, comprising:
the stacked wiring substrate according to claim 10; and
a semiconductor chip mounted on the first wiring substrate.
